(19) United States
(12) Patent Application Publication
(10) Pub. No.: US 2025/0133767 A1
(43) Pub. Date: Apr. 24, 2025

(54) SEMICONDUCTOR DEVICE

(71) Applicant: Murata Manufacturing Co., Ltd., Kyoto-fu (JP)

(72) Inventor: Akira FUJIHARA, Nagaokakyo-shi (JP)

(73) Assignee: Murata Manufacturing Co., Ltd., Kyoto-fu (JP)

(21) Appl. No.: 18/918,402

(22) Filed: Oct. 17, 2024

(30) Foreign Application Priority Data
Oct. 24, 2023 (JP) 2023-182461

(51) Int. Cl. H01L 29/78; H01L 27/12; H01L 29/45

(52) U.S. Cl. CPC H10D 30/637; H10D 30/601; H10D 64/62; H10D 86/201

(57) ABSTRACT

A field effect transistor includes a source region of a first conductive type on a device layer, a drain region of the first conductive type, a body region of a second conductive type that is opposite to the first conductive type, and a gate electrode on the device layer. The body region is directly below the gate electrode. When the insulating surface is in plan view, the gate electrode and the body region each have a shape elongated in a first direction, the source region is on one side of the gate electrode, and the drain region is on another side of the gate electrode. The field effect transistor further includes a body-contact region of the second conductive type extending from each of a plurality of body-contact connecting portions on an edge of the body region facing the source region toward the source region.

### CROSS-REFERENCE TO RELATED APPLICATION

This application claims benefit of priority to Japanese Patent Application No. 2023-182461, filed Oct. 24, 2023, the entire content of which is incorporated herein by reference.

### BACKGROUND

### Technical Field

The present disclosure relates to semiconductor devices.

### Background Art

When a MOSFET is operated at high voltage, electron-hole pairs are created in the body region directly below the gate electrode by an impact ionization phenomenon. To extract the created holes from the body region, a body-contact region connected to the body region is provided as described, for example, in U.S. Patent Application Publication No. 2019/0348514. The holes created in the body region move through the body region to reach

### SUMMARY

In the MOSFET described in U.S. Patent Application Publication No. 2019/0348514, the time of extracting holes created in the body region from the body region is long and, as a result, there is a possibility of decreasing withstand voltage.

Accordingly, the present disclosure provides a semiconductor device in which holes can be efficiently extracted from the body region of a MOSFET and a decrease in withstand voltage can be suppressed.

According to an aspect of the present disclosure, there is provided a semiconductor device including a device layer formed of a semiconductor arranged on an insulating surface; and a field effect transistor including a source region of a first conductive type formed on the device layer, a drain region of the first conductive type, a body region of a second conductive type that is opposite to the first conductive type, and a gate electrode arranged on the device layer. The body region is arranged directly below the gate electrode. When the insulating surface is in plan view, the gate electrode and the body region each have a shape elongated in a first direction, the source region is arranged on one side of the gate electrode, and the drain region is arranged on another side of the gate electrode. The field effect transistor further includes a body-contact region of the second conductive type extending from each of a plurality of body-contact connecting portions on an edge of the body region facing the source region toward the source region. The source region is connected to the body region at a plurality of source-body connecting portions other than the plurality of body-contact connecting portions. Each of the plurality of source-body connecting portions has a length in the first direction, the length having a maximum value that is eight times of a dimension in a second direction orthogonal to the first direction of the gate electrode or shorter.

When the maximum value of the length of each of the plurality of source-body connecting portions in the first direction is set eight times of the dimension of the gate electrode in the second direction or shorter, it is possible to keep high withstand voltage.

### BRIEF DESCRIPTION OF THE DRAWINGS

FIG. 1 is a plan view of a semiconductor device according to a first embodiment;

FIG. 2A and FIG. 2B are sectional views along a one-dot-chain line 2A-2A and a one-dot-chain line 2B-2B, respectively, of FIG. 1;

FIG. 3 is a plan view for describing a process in which holes created by impact ionization in a body region are extracted from the body region;

FIG. 4 is a graph representing calculation results regarding a relation between a length Wsb of a source-body connecting portion and electrical resistance Rbody of a movement path of holes;

FIG. 5 is a graph representing a relation between area efficiency and the length Wsb of the source-body connecting portion;

FIG. 6 is a graph representing a relation between withstand voltage and the length Wsb of the source-body connecting portion;

FIG. 7 is a plan view of a semiconductor device according to a second embodiment; and

FIG. 8 is a plan view of a semiconductor device according to a third embodiment.

### DETAILED DESCRIPTION

### First Embodiment

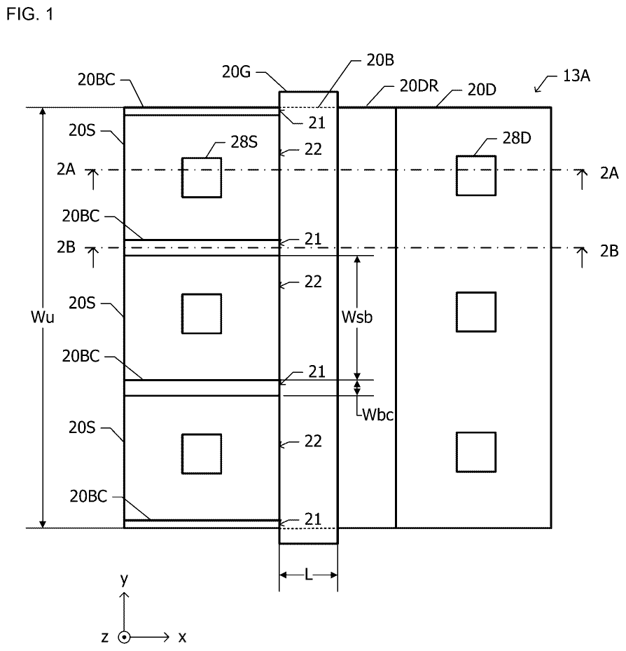

With reference to FIG. 1 to FIG. 6, a semiconductor device according to a first embodiment is described.

FIG. 1 is a plan view of the semiconductor device according to the first embodiment. The semiconductor device according to the first embodiment includes a field effect transistor, for example, MOSFET, provided on a SOI substrate.

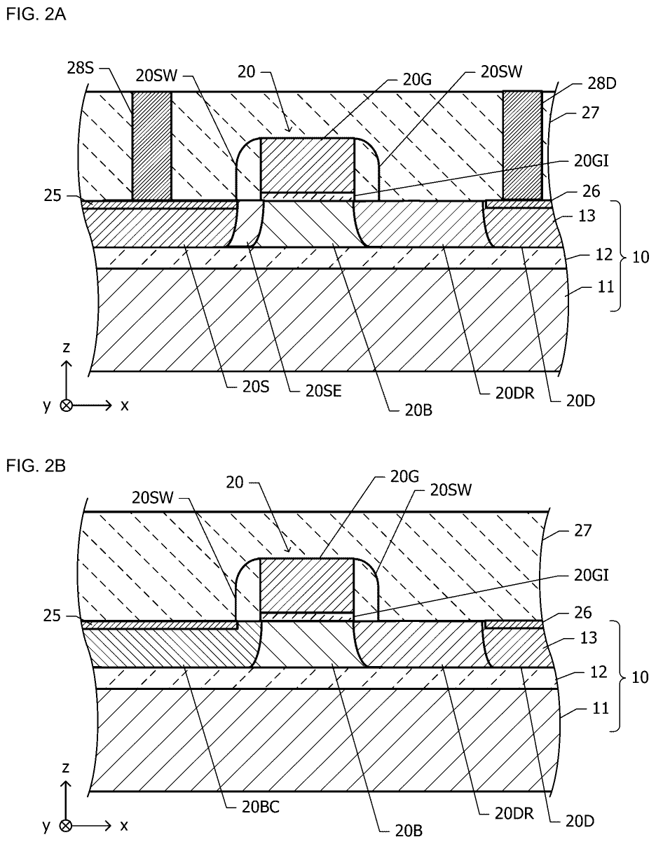

On a device layer of the SOI substrate (which will be described further below with reference to FIG. 2A and FIG. 2B), an active region 13A is defined. On the active region 13A, an n-type conductive source region 20S, a drift region 20DR, a drain region 20D, and a p-type conductive body region 20B are formed. A gate electrode 20G is arranged so as to almost overlap the body region 20B.

The gate electrode 20G has a shape elongated to one direction in plan view, and is arranged so as to cross the active region 13A. For example, the gate electrode 20G passes from one side of the rectangular active region 13A through the inside of the active region 13A to reach its opposite side. By taking the longitudinal direction (gate-width direction) of the gate electrode 20G as a y direction, the direction (gate-length direction) parallel to a surface of the device layer (paper surface of FIG. 1) and orthogonal to the y direction as an x direction, and a normal direction of the surface of the device layer as a z direction, an xyz orthogonal coordinate system is defined.

In plan view, the source region 20S is arranged on one side of the gate electrode 20G, and the drift region 20DR is arranged on the other side of the gate electrode 20G. At a position away from the drift region 20DR when viewed from the gate electrode 20G, the drain region 20D is arranged so as to be in contact with the drift region 20DR.

A p-type conductive body-contact region 20BC extends from each of a plurality of locations on an edge of the body region 20B facing a source region 20S toward the source region 20S. A connecting portion between the body-contact region 20BC and the body region 20B is referred to as a body-contact connecting portion 21. The body-contact connecting portion 21 indicates a portion of a p-type conductive region including the body region 20B and the body-contact region 20BC, the portion where the width in the y direction is changed. The source region 20S is configured of a plurality of portions obtained by isolation in the y direction by the plurality of body-contact regions 20BC. The source region 20S is connected to the body region 20B at a plurality of locations other than the plurality of body-contact connecting portions 21. A connecting portion between the source region 20S and the body region 20B is referred to as a source-body connecting portion 22. The source-body connecting portion 22 indicates a portion where n-type conductivity makes transition to p-type conductivity toward the x direction. The dimension (gate width) of the body region 20B in the y direction is denoted as Wu. The length of each body-contact connecting portion 21 in the y direction is denoted as Wbc, and the length of each source-body connecting portion 22 in the y direction is denoted as Wsb.

In plan view, a plurality of source-contact vias 28S are arranged at locations included in the source region 20S, and a plurality of drain-contact vias 28D are arranged at locations included in the drain region 20D. The source-contact vias 28S are electrically connected to the source region 20S and the body-contact region 20BC, and the drain-contact vias 28D are electrically connected to the drain region 20D.

FIG. 2A and FIG. 2B are sectional views along a one-dot-chain line 2A-2A and a one-dot-chain line 2B-2B, respectively, of FIG. 1. A SOI substrate 10 includes a support substrate 11 made of silicon, an insulating layer (referred to as a buried oxide film 12), and a device layer 13. The device layer 13 is arranged on an insulating surface of the buried oxide film 12. An element isolation region (not depicted) is formed on the device layer 13, and the active region 13A (FIG. 1) surrounded by the element isolation region is defined. On the active region 13A of the device layer 13, the gate electrode 20G is arranged via a gate insulating film 20GI. Side surfaces of the gate electrode 20G are covered with sidewall spacers 20SW.

As depicted in FIG. 2A, the p-type conductive body region 20B, the n-type conductive source region 20S, a source extension region 20SE, the drift region 20DR, and the drain region 20D are arranged in the device layer 13. The body region 20B, the source region 20S, the source extension region 20SE, the drift region 20DR, and the drain region 20D reach from the upper surface of the device layer 13 to an interface between the device layer 13 and the buried oxide film 12.

The body region 20B is arranged directly below the gate electrode 20G. For example, in plan view, the body region 20B is included in the gate electrode 20G, and the dimension of the body region 20B in the x direction on the surface of the device layer 13 is shorter than the dimension of the gate electrode 20G in the x direction. The source extension region 20SE is arranged directly below the sidewall spacer 20SW on one side of the gate electrode 20G. Directly below the sidewall spacer 20SW on the other side, a tip portion of the drift region 20DR is arranged.

The source extension region 20SE and the drift region 20DR are in contact with the body region 20B via a pn-junction interface. The source region 20S is connected to the body region 20B via the source extension region 20SE. In the specification, the source region 20S and the source extension region 20SE are collectively referred to as the source region 20S. The drain region 20D is connected to the body region 20B via the drift region 20DR.

On the upper surface of the source region 20S, a silicide film 25 is arranged. On the upper surface of the drain region 20D, a silicide film 26 is arranged. An interlayer insulating film 27 is arranged on the device layer 13 so as to cover the gate electrode 20G and the sidewall spacers 20SW. In the interlayer insulating film 27, the source-contact via 28S and the drain-contact via 28D are arranged. The source-contact via 28S is electrically connected to the source region 20S via the silicide film 25. The drain-contact via 28D is electrically connected to the drain region 20D via the silicide film 26.

In the section depicted in FIG. 2B, inside the device layer 13, the body-contact region 20BC is arranged so as to be in contact with the body region 20B. The body region 20B and the body-contact region 20BC both have p-type conductivity and are electrically connected to each other. The silicide film 25 arranged on the upper surface of the source region 20S (FIG. 2A) continuously covers up to the upper surface of the body-contact region 20BC. The source-contact via 28S is electrically connected also to the body-contact region 20BC via the silicide film 25. Thus, to the body-contact region 20BC, a potential equal to that of the source region 20S, generally, a ground potential, is applied.

Next, a general outline of a method of manufacturing the semiconductor device according to the first embodiment is described. The SOI substrate 10 formed of the support substrate 11, the buried oxide film 12, and the device layer 13 is prepared. After the element isolation region (not depicted) is formed on the device layer 13 to define the active region 13A (FIG. 1), a p-type dopant, such as boron, for forming the body region 20B and the body-contact region 20BC is injected into the active region 13A.

Then, oxidation treatment is performed to form a silicon oxide film serving as the gate insulating film 20GI over the entire surface of the device layer 13. Furthermore, a polysilicon film serving as the gate electrode 20G is deposited, and an n-type dopant is injected into the polysilicon film. By patterning the silicon oxide film and the polysilicon film, the gate insulating film 20GI and the gate electrode 20G are obtained. Note that, as required, an insulating film may be formed on the polysilicon film. This insulating film has a function of preventing injection of the dopant into the gate electrode 20G when the gate electrode 20G is used as a mask in a subsequent ion injecting process. Also, before ion injection into the device layer 13, a through oxide film may be formed as required.

With the gate electrode 20G as a mask, injection of a p-type dopant for forming a halo region (not depicted) and injection of an n-type dopant for forming the source extension region 20SE are performed. Next, with the resist pattern (not depicted) and the gate electrode 20G as masks, injection of a p-type dopant for forming the body-contact region 20BC is performed. Furthermore, with another resist pattern (not depicted) and the gate electrode 20G as masks, injection of an n-type dopant for forming the drift region 20DR is performed. The dopant injected into the device layer 13 on a drain region 20D side at the time of injection of the dopant for forming the source extension region 20SE is absorbed to the drift region 20DR. Then, the sidewall spacers 20SW are formed.

Next, still another resist pattern (not depicted), the gate electrode 20G, and the sidewall spacers 20SW as masks, injection of an n-type dopant for forming the source region 20S and the drain region 20D is performed. Directly below the sidewall spacer 20SW on a source region 20S side, the source extension region 20SE (FIG. 2A) by the n-type dopant is left.

Activation annealing of the dopant injected into the device layer 13 may be performed for each dopant injection, or may be performed after the process of injecting all dopants.

Next, the silicide film 25 is formed on the upper surface of the source region 20S and the body-contact region 20BC, and the silicide film 26 is formed on the upper surface of the drain region 20D. The silicide films 25 and 26 can be formed by depositing a metal film made of, for example, cobalt or titanium, and then reacting the metal film with silicon. Then, the interlayer insulating film 27, the source-contact via 28S, the drain-contact via 28D, and so forth are formed.

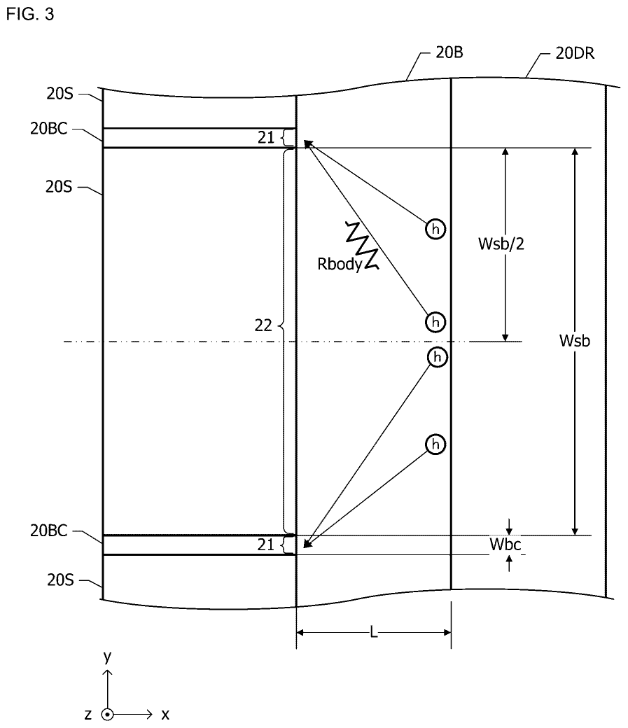

Next, with reference to FIG. 3, a process is described in which holes created by impact ionization in the body region 20B are extracted from the body region 20B.

FIG. 3 is a plan view for describing the process in which holes created by impact ionization in the body region 20B are extracted from the body region 20B. The source region 20S arranged on one side (left side in FIG. 3) of the body region 20B elongated in the y direction is in contact with the body region 20B at the source-body connecting portion 22. From the body-contact connecting portion 21 of the body region 20B toward a side where the source region 20S is arranged, the body-contact region 20BC extends. On the other side (right side in FIG. 3) of the body region 20B, the drift region 20DR is arranged.

At the time of high-voltage operation, mainly near the interface between the body region 20B and the drift region 20DR, electron-hole pairs are created by impact ionization. The created electrons reach the drain region 20D (FIG. 1) via the n-type conductive drift region 20DR. While holes h move inside the body region 20B toward the source region 20S, they do not reach the source region 20S due to the potential barrier created at a pn-junction interface between the source region 20S and the body region 20B.

The holes h reach the body-contact region 20BC connected to the body region 20B. These holes h reach a ground potential region via the body-contact region 20BC, the silicide film 25 (FIG. 2B), and the source-contact via 28S (FIG. 2A). To reach the body-contact region 20BC, the holes h have to move inside the body region 20B not only in the x direction but also in the y direction. To efficiently extract the holes h from the body region 20B, it is desired to decrease electrical resistance of a path where the holes h created by impact ionization move.

The movement path of the holes h created at the center of the source-body connecting portion 22 with respect to the y direction to the body-contact region 20BC is the longest. Electrical resistance of this movement path is denoted as Rbody. The dimension of the body region 20B in the x direction is substantially equal to the dimension (gate length L) of the gate electrode 20G in the x direction. The dimension of the gate length L is determined by the frequency or the like of a high frequency signal taken as a target and, by way of example, shorter than or equal to 0.4 μm.

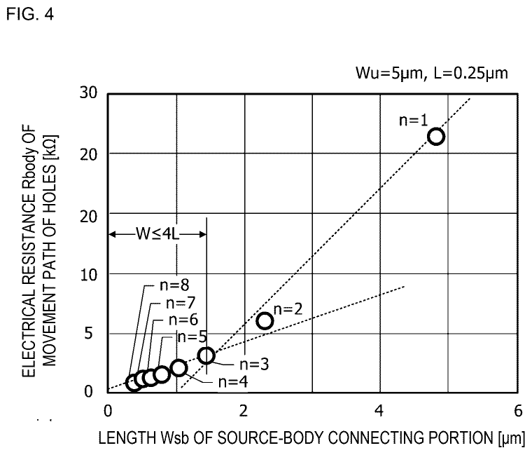

Next, with reference to FIG. 4, a relation between the length Wsb of the source-body connecting portion 22 and the electrical resistance Rbody of the movement path of the holes h is described. FIG. 4 is a graph representing calculation results regarding the relation between the length Wsb of the source-body connecting portion 22 and the electrical resistance Rbody of the movement path of the holes h. The horizontal axis represents the length Wsb of the source-body connecting portion 22 in units [μm], and the vertical axis

represents the electrical resistance Rbody in units [Ω]. Note that the gate length L is set at 0.25 μm, a gate width Wu is set at 5 μm, and the length Wbc of the body-contact connecting portion 21 in the y direction is set at 0.2 μm.

Note that the length Wbc in the y direction of the body-contact connecting portion 21 that is positioned at each end in the y direction is set at ½ of the length Wbc of the body-contact connecting portion 21 in the y direction at a location other than each end, that is, 0.1 μm. Thus, two body-contact regions 20BC at both ends are counted as one. Also, sheet resistance of the body region 20B is set at 1×10¹⁷ Ω/sq.

Each numerical value attached to a circle depicted in FIG. 4 is a count n of body-contact regions 20BC. In a structure with the count n being 1, the body-contact region 20BC is arranged at each end of the body region 20B in the y direction. In a structure with the count n of body-contact regions 20BC being 2 or more, the body-contact regions 20BC are arranged so that the length Wsb of each of the plurality of source-body connecting portions 22 is equal. For example, in a structure with the count n being 2, the body-contact region 20BC is arranged at each of both ends of the body region 20B in the y direction, and the body-contact regions 20BC is arranged also at the center of the body region 20B in the y direction. Here, the length Wsb of each source-body connecting portion 22 is 2.3 μm.

If the length Wsb of the source-body connecting portion 22 increases, the movement distance of the holes h to the body-contact region 20BC increases, and thus the electrical resistance Rbody increases. In a range in which the length Wsb of the source-body connecting portion 22 is shorter than 4 L, the gate length L is more dominant than the length Wsb in the length of the movement path of the holes h. In a range in which the length Wsb of the source-body connecting portion 22 is longer than or equal to 4 L, the length Wsb is dominant in the length of the movement path of the holes h.

Thus, if the length Wsb is longer than 4 L, compared with the case in which the length Wsb is shorter than 4 L, the gradient of the increase of the electrical resistance Rbody with respect to the increase of the length Wsb increases. In view of suppressing the increase in the electrical resistance Rbody, the length Wsb is preferably set shorter than or equal to 4 L. When the length Wsb of each of the plurality of source-body connecting portions 22 is not constant, the maximum value of the length Wsb is preferably set shorter than or equal to 4 L.

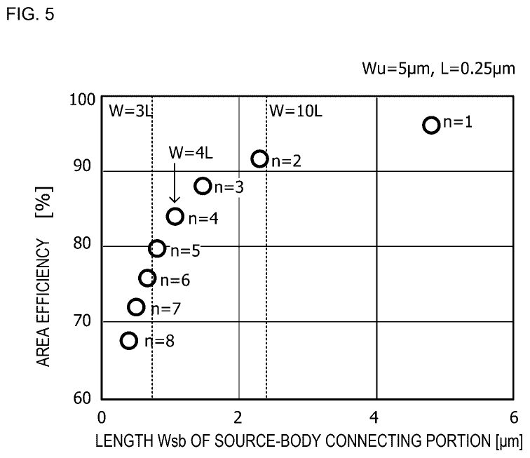

Next, with reference to FIG. 5, a relation between area efficiency and the length Wsb of the source-body connecting portion 22 is described. FIG. 5 is a graph representing the relation between the area efficiency and the length Wsb of the source-body connecting portion 22. The horizontal axis represents the length Wsb in units [μm], and the vertical axis represents the area efficiency in units [%]. Here, the area efficiency refers to a total ratio of the lengths Wsb of the source-body connecting portions 22 with respect to the gate width Wu. The area efficiency can be considered as a ratio of usable regions substantially as channels in the body region 20B.

Also in FIG. 5, as with FIG. 4, the gate length L is set at 0.25 μm, and the gate width Wu is set at 5 μm. The length Wbc of the body-contact connecting portion 21 in the y direction and the method of taking the count n of the body-contact regions 20BC are the same as those in FIG. 4. Each numerical value attached to a circle depicted in FIG. 5 is the count n of body-contact regions 20BC.

As the length Wsb is shorter, the area efficiency decreases. In particular, in a range in which the length Wsb is shorter than 3 L, the decrease in area efficiency is significant. To avoid a significant decrease in area efficiency, it is preferable to set the length Wsb at a value longer than or equal to 3 L. When the length Wsb of each of the plurality of source-body connecting portions 22 is not constant, the minimum value of the length Wsb is preferably set longer than or equal to 3 L.

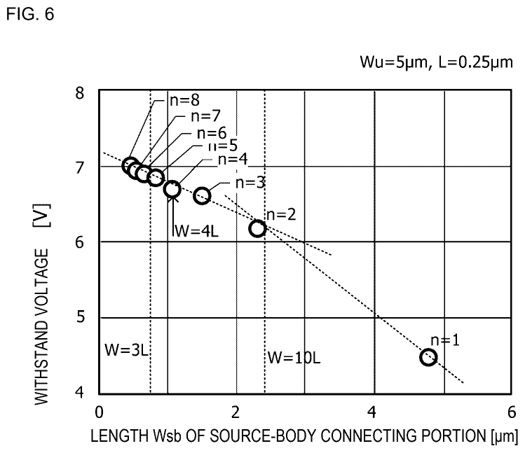

Next, with reference to FIG. 6, a relation between the withstand voltage and the length Wsb is described. The withstand voltage is an actually measured value. FIG. 6 is a graph representing the relation between the withstand voltage and the length Wsb of the source-body connecting portion 22. The horizontal axis represents the length Wsb in units [μm], and the vertical axis represents the withstand voltage in units [V]. Also in FIG. 6, as with FIG. 4, the gate length L is set at 0.25 μm, and the gate width Wu is set at 5 μm. The length Wbc of the body-contact connecting portion 21 in the y direction and the method of taking the count n of the body-contact regions 20BC are the same as those in FIG. 4. Each numerical value attached to a circle depicted in FIG. 6 is the count n of body-contact regions 20BC.

As the length Wsb is longer, the withstand voltage decreases. When the length Wsb exceeds 10 L, the decrease amount of the withstand voltage increases with respect to the increase in the length Wsb. To keep high withstand voltage, it is preferable to set the length Wsb, by way of example, shorter than or equal to 10 L.

Next, a preferable thickness of the device layer 13 is described.

In a structure in which the source region 20S (FIG. 2A) does not reach the interface between the device layer 13 and the buried oxide film 12, a p-type conductive region, which is the same as the body region 20B, is allocated between the source region 20S and the buried oxide film 12. In this structure, even if the body-contact region 20BC is arranged with a gap from the body region 20B, holes can be extracted from the body region 20B through the p-type conductive region between the source region 20S and the buried oxide film 12.

As depicted in FIG. 2A, when the source region 20S reaches the interface between the device layer 13 and the buried oxide film 12 from the upper surface of the device layer 13, if the body-contact region 20BC is arranged with a gap from the body region 20B, the holes inside the body region 20B cannot reach the body-contact region 20BC. When the source region 20S reaches the interface between the device layer 13 and the buried oxide film 12 from the upper surface of the device layer 13, a significant effect can be obtained from the structure in which the body-contact region 20BC is arranged so as to be in contact with the body region 20B. When the thickness of the device layer 13 is 50 nm or less, it is difficult to allocate a p-type conductive region between the source region 20S and the buried oxide film 12. Therefore, when the thickness of the device layer 13 is 50 nm or less, a significant effect can be obtained from adoption of the structure of the first embodiment.

Next, a semiconductor device according to a modification of the first embodiment is described.

The semiconductor device according to the first embodiment includes an n-channel MOSFET. In addition, the semiconductor device may include a p-channel MOSFET. Also in the p-channel MOSFET, a preferable relation between the length Wsb and the gate length L is similar to that of the n-channel MOSFET.

In the first embodiment (FIG. 1), one gate electrode 20G is arranged so as to cross one active region 13A. In addition, it is also possible to adopt the structure according to the first embodiment in a multifinger MOSFET where a plurality of gate electrodes 20G crossing one active region 13A are arranged. In the multifinger MOSFET, the gate width Wu can be considered as a dimension of each of the plurality of fingers of the gate electrode 20G in a gate-width direction.

### Second Embodiment

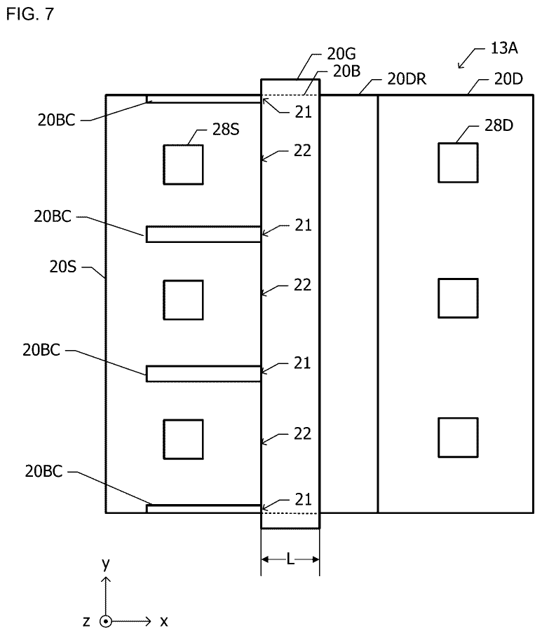

Next, with reference to FIG. 7, a semiconductor device according to a second embodiment is described. In the following, description of structures common to those of the semiconductor device according to the first embodiment described with reference to FIG. 1 to FIG. 6 is omitted.

FIG. 7 is a plan view of the semiconductor device according to the second embodiment.

In the first embodiment (FIG. 1), each body-contact region 20BC extends from the body-contact connecting portion 21 of the body region 20B to the source region 20S side, and reaches an opposite edge of the source region 20S. By contrast, in the second embodiment, each body-contact region 20BC extending from the body-contact connecting portion 21 does not reach the opposite edge of the source region 20S. Thus, the source region 20S is not isolated by the body-contact regions 20BC, and is configured of a one continuous region.

Also in the second embodiment, as with the first embodiment, holes created in the body region 20B move the inside of the body region 20B, and reaches the body-contact region 20BC through the body-contact connecting portion 21. In this manner, also in the second embodiment, the process of extracting the holes in the body-contact region 20BC is the same as that of the first embodiment.

Next, an excellent effect of the second embodiment is described.

Also in the second embodiment, by setting the relation between the length Wsb of the source-body connecting portion 22 and the gate length L satisfying the relation in the first embodiment, it is possible to obtain an excellent effect similar to that of the first embodiment.

### Third Embodiment

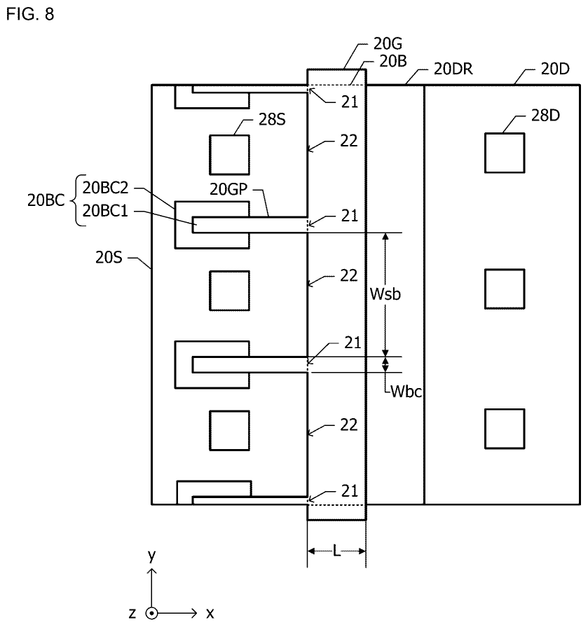

Next, with reference to FIG. 8, a semiconductor device according to a third embodiment is described. In the following, description of structures common to those of the semiconductor device according to the first embodiment described with reference to FIG. 1 to FIG. 6 is omitted.

FIG. 8 is a plan view of the semiconductor device according to the third embodiment. In the third embodiment, the body-contact region 20BC is configured of a first body-contact region 20BC1 and a second body-contact region 20BC2. The first body-contact region 20BC1 extends, as with the first embodiment (FIG. 1), from the body-contact connecting portion 21 of the body region 20B toward a source region 20S side. As with the body-contact region 20BC of the second embodiment (FIG. 7), the first body-contact region 20BC1 does not reach the opposite edge of the source region 20S.

A gate-electrode protruding portion 20GP protruding from the gate electrode 20G toward a source region 20S side overlaps the first body-contact region 20BC1 in plan view. When an n-type dopant is injected into the source region 20S, the gate-electrode protruding portion 20GP acts as a mask. Thus, the first body-contact region 20BC1 directly below the gate-electrode protruding portion 20GP has p-type conductivity, which is similar to the body region 20B, and the concentration of the dopant of the first body-contact region 20BC1 is equal to the concentration of the dopant of the body region 20B.

The second body-contact region 20BC2 having p-type conductivity is formed so as to surround the tip of the first body-contact region 20BC1 from three directions. The concentration of the p-type dopant of the second body-contact region 20BC2 is higher than the concentration of the p-type dopant of the first body-contact region 20BC1. As with the silicide film 25 (FIG. 2A) of the first embodiment, a silicide film is arranged on the upper surface of the source region 20S and the second body-contact region 20BC2. Holes moving the inside of the body region 20B to reach the body-contact connecting portion 21 reach a region of the ground potential via the first body-contact region 20BC1 and the second body-contact region 20BC2.

Next, an excellent effect of the third embodiment is described.

In the third embodiment, the length Wbc of the body-contact connecting portion 21 is substantially equal to the dimension of the gate-electrode protruding portion 20GP in the y direction. In general, processing accuracy of the gate electrode 20G is higher compared with processing accuracy of the other components. Thus, it is possible to shorten the length Wbc of the body-contact connecting portion 21 without depending on the dimension of the second body-contact region 20BC2. In other words, it is possible to lengthen the length Wsb of the source-body connecting portion 22. Thus, it is possible to enhance area efficiency.

Also in the third embodiment, by setting the relation between the length Wsb of the source-body connecting portion 22 and the gate length L satisfying the relation in the first embodiment, it is possible to obtain an excellent effect similar to that of the first embodiment.

Each of the above-described embodiments is merely an example, and it goes without saying that partial replacement or combination of the structures described in different embodiments is possible. Operations and effects similar to those by similar structures of the plurality of embodiments are not mentioned one by one for each embodiment. Furthermore, the present disclosure is not limited to the above-described embodiments. For example, it should be obvious for a person skilled in the art that various changes, improvements, combinations, and so forth are possible.

The following disclosure is disclosed based on the above-described embodiments in the specification.
<1> A semiconductor device including a device layer formed of a semiconductor arranged on an insulating surface; and a field effect transistor including a source region of a first conductive type formed on the device layer, a drain region of the first conductive type, a body region of a second conductive type that is opposite to the first conductive type, and a gate electrode arranged on the device layer. The body region is arranged directly below the gate electrode. When the insulating surface is in plan view, the gate electrode and the body region each have a shape elongated in a first direction, the source region is arranged on one side of the gate electrode, and the drain region is arranged on another side of the gate electrode. The field effect transistor further includes a body-contact region of the second conductive type extending from each of a plurality of body-contact connecting portions on an edge of the body region facing the source region toward the source region. The source region is connected to the body region at a plurality of source-body connecting portions other than the plurality of body-contact connecting portions. Each of the plurality of source-body connecting portions has a length in the first direction, the length having a maximum value that is ten times of a dimension in a second direction orthogonal to the first direction of the gate electrode or shorter.
<2> The semiconductor device according to <1>, in which each of the plurality of source-body connecting portions has the length in the first direction, the length having the maximum value that is four times of the dimension in the second direction orthogonal to the first direction of the gate electrode or shorter.
<3> The semiconductor device according to <1> or <2>, in which each of the plurality of source-body connecting portions has the length in the first direction, the length having a minimum value that is three times of the dimension in the second direction orthogonal to the first direction of the gate electrode or longer.
<4> The semiconductor device according to any one of <1> to <3>, in which the source region reaches the insulating surface from an upper surface of the device layer.
<5> The semiconductor device according to any one of <1> to <4>, in which the device layer has a thickness smaller than or equal to 50 nm.
<6> The semiconductor device according to any one of <1> to <5>, in which a drift region arranged between the body region and the drain region, being of the first conductive type, and being lower in concentration than the drain region.

What is claimed is:

1. A semiconductor device comprising:
a device layer including a semiconductor on an insulating surface; and
a field effect transistor including a source region of a first conductive type on the device layer, a drain region of the first conductive type, a body region of a second conductive type that is opposite to the first conductive type, and a gate electrode on the device layer, wherein
the body region is directly below the gate electrode,
when the insulating surface is in plan view, the gate electrode and the body region each have a shape elongated in a first direction, the source region is on one side of the gate electrode, and the drain region is on another side of the gate electrode,
the field effect transistor further includes a body-contact region of the second conductive type extending from each of a plurality of body-contact connecting portions on an edge of the body region facing the source region toward the source region,
the source region is connected to the body region at a plurality of source-body connecting portions other than the plurality of body-contact connecting portions, and
each of the plurality of source-body connecting portions has a length in the first direction, the length having a maximum value that is ten times of a dimension in a second direction orthogonal to the first direction of the gate electrode or shorter.

2. The semiconductor device according to claim 1, wherein
each of the plurality of source-body connecting portions has the length in the first direction, the length having the maximum value that is four times of the dimension in the second direction orthogonal to the first direction of the gate electrode or shorter.

3. The semiconductor device according to claim 1, wherein
each of the plurality of source-body connecting portions has the length in the first direction, the length having a minimum value that is three times of the dimension in the second direction orthogonal to the first direction of the gate electrode or longer.

4. The semiconductor device according to claim 1, wherein
the source region reaches the insulating surface from an upper surface of the device layer.

5. The semiconductor device according to claim 1, wherein
the device layer has a thickness smaller than or equal to 50 nm.

6. The semiconductor device according to claim 1, further comprising:
a drift region between the body region and the drain region, being of the first conductive type, and being lower in concentration than the drain region.

7. The semiconductor device according to claim 2, wherein
each of the plurality of source-body connecting portions has the length in the first direction, the length having a minimum value that is three times of the dimension in the second direction orthogonal to the first direction of the gate electrode or longer.

8. The semiconductor device according to claim 2, wherein
the source region reaches the insulating surface from an upper surface of the device layer.

9. The semiconductor device according to claim 2, wherein
the device layer has a thickness smaller than or equal to 50 nm.

10. The semiconductor device according to claim 2, further comprising:
a drift region between the body region and the drain region, being of the first conductive type, and being lower in concentration than the drain region.
